(19) United States
(12) Patent Application Publication
(10) Pub. No.: US 2025/0297405 A1
(43) Pub. Date: Sep. 25, 2025

(54) METHOD FOR MANUFACTURING GALLIUM NITRIDE SUBSTRATE

(71) Applicant: DISCO CORPORATION, Tokyo (JP)

(72) Inventor: Asahi NOMOTO, Tokyo (JP)

(21) Appl. No.: 19/071,294

(22) Filed: Mar. 5, 2025

(30) Foreign Application Priority Data
Mar. 25, 2024 (JP) 2024-048419

(51) Int. Cl. C30B 33/00; C30B 29/40; C30B 29/66

(52) U.S. Cl. CPC C30B 33/00; C30B 29/406; C30B 29/66

(57) ABSTRACT

A method for manufacturing a gallium nitride substrate from a gallium nitride ingot includes: holding the gallium nitride ingot; forming a separating layer at a depth corresponding to a thickness of the gallium nitride substrate to be manufactured, by positioning a focal point of a laser beam inside the gallium nitride ingot and relatively moving the gallium nitride ingot and the focal point along a direction of a crystal orientation represented by the following formula (1) of the gallium nitride ingot; and separating the gallium nitride substrate from the gallium nitride ingot with the separating layer as a starting point. The separating includes forming a plurality of focal points by branching the laser beam and setting the focal points such that a straight line connecting the branched focal points is along a direction parallel to a direction of a crystal orientation represented by the following formula (2).

[symbol]

1 0 1̅ 0 [symbol] formula (1)

[symbol]

1 1 2̅ 0 [symbol] formula (2)

### CROSS-REFERENCE TO RELATED APPLICATION(S)

The present application claims priority to and incorporates by reference the entire contents of Japanese Patent Application No. 2024-048419 filed in Japan on Mar. 25, 2024.

### TECHNICAL FIELD

The present invention relates to a method for manufacturing a gallium nitride substrate.

### BACKGROUND

Gallium nitride (GaN) has a band gap three times larger than silicon (Si), and therefore use thereof as a device such as a power device or a light emitting diode (LED) has been studied. It is known that a gallium nitride substrate (GaN substrate) is cut from a gallium nitride ingot (GaN ingot) using an inner peripheral blade that can be thinner than an outer peripheral blade (see, for example, JP 2011 084469 A).

However, even when the GaN substrate is cut out from the GaN ingot using the inner peripheral blade, since the thickness of the inner peripheral blade is, for example, about 0.3 mm with respect to the thickness of the GaN substrate (for example, 150 μm), 60 to 70% of the GaN ingot is scraped off during cutting and discarded, and there is a problem that it is uneconomical.

### SUMMARY

A method according to the present disclosure is for manufacturing a gallium nitride substrate from a gallium nitride ingot having a first surface and a second surface on a side opposite to the first surface. The method includes: holding the gallium nitride ingot; forming a separating layer at a depth corresponding to a thickness of the gallium nitride substrate to be manufactured, by positioning a focal point of a laser beam having a wavelength transmissive to gallium nitride inside the gallium nitride ingot from the first surface and relatively moving the gallium nitride ingot and the focal point along a direction of a crystal orientation represented by the following formula (1) of the gallium nitride ingot; and separating the gallium nitride substrate from the gallium nitride ingot with the separating layer as a starting point. The separating includes forming a plurality of focal points by branching the laser beam and setting the focal points such that a straight line connecting the branched focal points is along a direction parallel to a direction of a crystal orientation represented by the following formula (2).

[symbol]

1 0 1̅ 0 [symbol] formula (1)

[symbol]

1 1 2̅ 0 [symbol] formula (2)

### BRIEF DESCRIPTION OF THE DRAWINGS

FIG. 1 is a perspective view illustrating an example of a gallium nitride ingot used in a method for manufacturing a gallium nitride substrate according to an embodiment;

FIG. 2 is a top view for explaining a crystal orientation of the gallium nitride ingot of FIG. 1;

FIG. 3 is a flowchart illustrating a processing procedure of the method for manufacturing a gallium nitride substrate according to the embodiment;

FIG. 4 is a cross-sectional view for explaining a holding step and a separating layer forming step in FIG. 3;

FIG. 5 is a top view for explaining the separating layer forming step in FIG. 3;

FIGS. 6A to 6D are top views for explaining branching of a laser beam in the separating layer forming step in FIG. 3;

FIG. 7 is a top view for explaining processing marks formed by a laser beam in the separating layer forming step in FIG. 3;

FIG. 8 is a cross-sectional view for explaining a separating step in FIG. 3; and

FIG. 9 is a cross-sectional view for explaining the separating step in FIG. 3.

### DETAILED DESCRIPTION

An embodiment of the present disclosure will be described in detail with reference to the drawings. The present invention is not limited by the contents described in the following embodiment. In addition, the components described below include those that can be easily assumed by a person skilled in the art and those that are substantially the same. Furthermore, the configurations described below can be appropriately combined. In addition, various omissions, substitutions, or changes in the configurations can be made without departing from the gist of the present invention.

### Embodiment

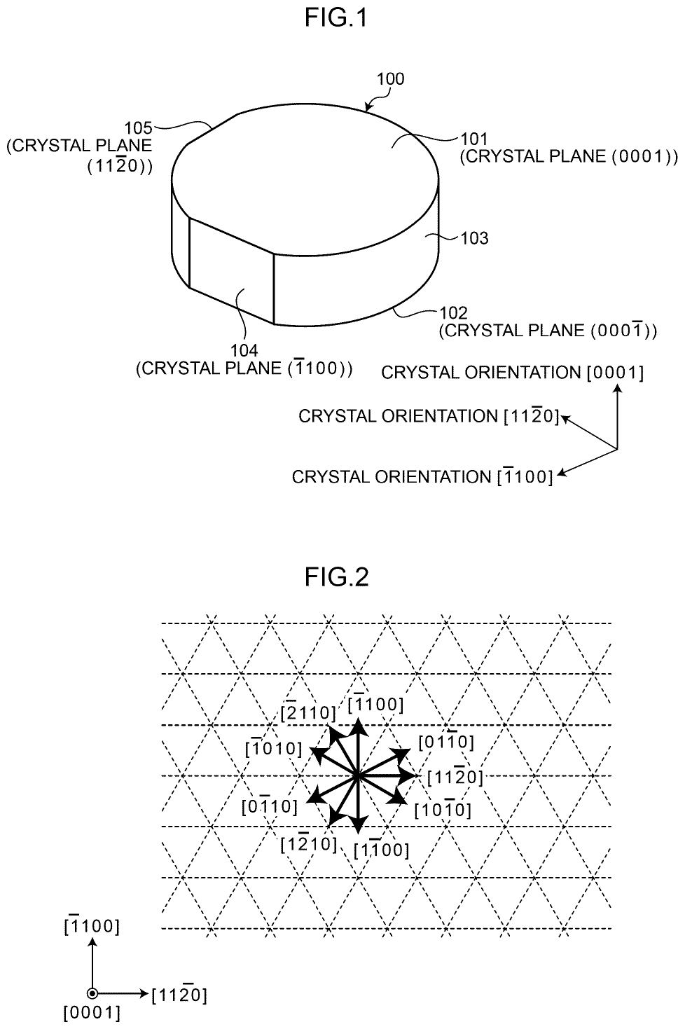

A method for manufacturing a gallium nitride substrate according to an embodiment will be described with reference to the drawings. FIG. 1 is a perspective view illustrating a gallium nitride ingot 100 which is an example of a gallium nitride ingot used in the method for manufacturing a gallium nitride substrate according to the embodiment. FIG. 2 is a top view for explaining a crystal orientation of the gallium nitride ingot 100 of FIG. 1. The method for manufacturing a gallium nitride substrate according to the embodiment is a method for manufacturing a gallium nitride substrate (GaN substrate, GaN wafer) 130 (see FIG. 9) from the gallium nitride ingot (GaN ingot) 100. The GaN ingot 100 is a gallium nitride (GaN) single crystal having a hexagonal crystal structure. Note that a conductivity type of the GaN ingot 100 is not particularly limited. The GaN ingot 100 may be p-type containing p-type impurities such as magnesium (Mg) and beryllium (Be), or may be n-type containing n-type impurities such as silicon (Si) and germanium (Ge).

In the present embodiment, as illustrated in FIG. 1, the GaN ingot 100 is formed in a cylindrical shape as a whole, and has a flat circular first surface 101 exposed upward, a flat circular second surface 102 exposed downward on a side opposite to the first surface 101, and a peripheral surface 103 located between the first surface 101 and the second surface 102. The GaN ingot 100 has a diameter of 4 inches (about 100 mm) and a thickness of 500 μm, but the diameter and the thickness are not limited to these values.

As illustrated in FIG. 1, flat rectangular orientation flats 104 and 105 are formed on the peripheral surface 103 of the GaN ingot 100. The GaN ingot 100 is not limited to this in the present invention, and notches extending in an axial direction orthogonal to the first surface 101 and the second surface 102 may be formed at similar positions on the peripheral surface 103 instead of the orientation flats 104 and 105.

In the present disclosure, a crystal orientation and a crystal plane of a GaN single crystal are specified using Miller indices. In the present disclosure, a specific crystal orientation is expressed using [ ], and crystal orientations equivalent to each other due to symmetry of a crystal structure are expressed using < >. In addition, a specific crystal plane is expressed using ( ), and crystal planes equivalent to each other due to symmetry of a crystal structure are expressed using { }.

As for the first surface 101 and the second surface 102, as illustrated in FIG. 1, the first surface 101 corresponds to the following crystal plane (1-1) and is orthogonal to the following crystal orientation (2-1). The second surface 102 corresponds to the following crystal plane (1-2) and is orthogonal to the following crystal orientation (2-2). The orientation flat 104 has a planar shape, corresponds to the following crystal plane (1-3), and is orthogonal to the following crystal orientation (2-3). The orientation flat 105 has a planar shape, corresponds to the following crystal plane (1-4), and is orthogonal to the following crystal orientation (2-4). That is, the GaN ingot 100 is manufactured such that the following crystal plane (1-1) is exposed to the first surface 101, such that the following crystal plane (1-2) is exposed to the second surface 102, such that the following crystal plane (1-3) is exposed to the orientation flat 104, and such that the following crystal plane (1-4) is exposed to the orientation flat 105. Alternatively, the GaN ingot 100 may be manufactured such that the following crystal plane (1-3) is exposed to the orientation flat 105 and such that the following crystal plane (1-4) is exposed to the orientation flat 104. The crystal orientations (2-1), (2-3), and (2-4) are orthogonal to each other. Therefore, the orientation flat 104 is formed parallel to the crystal orientation (2-4), and the orientation flat 105 is formed parallel to the crystal orientation (2-3).

(0 0 0 1) crystal plane (1-1)

(0 0 0 1̅) crystal plane (1-2)

(1̅ 1 0 0) crystal plane (1-3)

(1̅ 1 2 0) crystal plane (1-4)

[0 0 0 1] crystal orientation (2-1)

[0 0 0 1̅] crystal orientation (2-2)

[1̅ 1 0 0] crystal orientation (2-3)

[1 1 2̅ 0] crystal orientation (2-4)

Three crystal orientations (2-4), (2-5), and (2-6) forming an angle of 120° with each other illustrated in FIG. 2 all belong to a crystal orientation represented by the following formula (2) expressing the crystal orientations equivalent to each other due to symmetry of a hexagonal crystal structure of the GaN ingot 100.

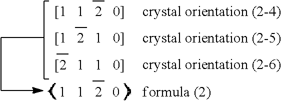

The GaN ingot 100 has a property that the following crystal plane (3-3) including the crystal plane (1-4) is less likely to be a cleavage plane than the following crystal plane (3-1) including the crystal planes (1-1) and (1-2) and the following crystal plane (3-2) including the crystal plane (1-3). That is, the GaN ingot 100 has a property of being less likely to be cleaved along the crystal plane (3-3) than along the crystal planes (3-1) and (3-2).

{0 0 0 1} crystal plane (3-1)

{1̅ 1 0 0} crystal plane (3-2)

{1 1 2̅ 0} crystal plane (3-3)

Three crystal orientations (2-3), (2-7), and (2-8) forming an angle of 120° with each other and three crystal orientations (2-9), (2-10), and (2-11) forming an angle of 120° with each other illustrated in FIG. 2 all belong to a crystal orientation represented by the following formula (1) expressing the crystal orientations equivalent to each other due to symmetry of a hexagonal crystal structure of the GaN ingot 100.

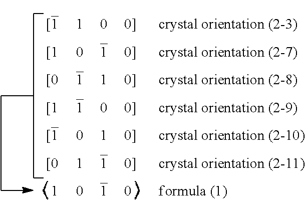

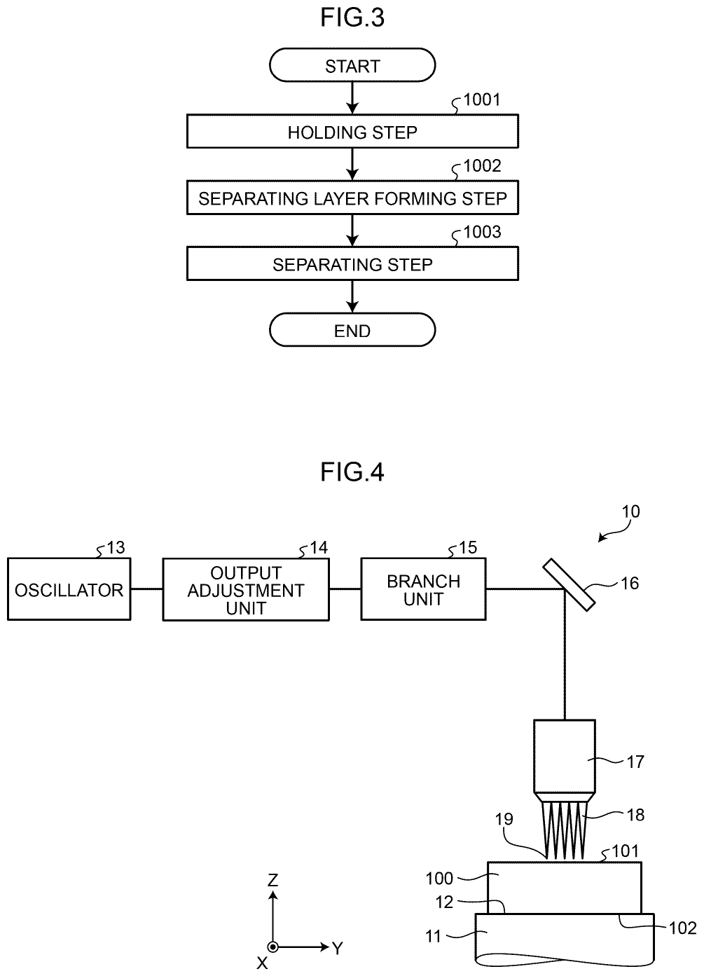

Next, the method for manufacturing a gallium nitride substrate according to the embodiment will be described with reference to the drawings. FIG. 3 is a flowchart illustrating a processing procedure of the method for manufacturing a gallium nitride substrate according to the embodiment. The method for manufacturing a gallium nitride substrate according to the embodiment is a method for manufacturing the GaN substrate 130 from the GaN ingot 100, and includes a holding step 1001, a separating layer forming step 1002, and a separating step 1003. The method for manufacturing a gallium nitride substrate according to the embodiment is a manufacturing method performed by forming a separating layer 110 in the GaN ingot 100 and breaking the GaN ingot 100 along the crystal plane (3-1) owing to the presence of the separating layer 110 to separate the GaN substrate 130 from the GaN ingot 100, and is a method capable of reducing cleavage along the crystal plane (3-2) as compared with related art by arranging a plurality of focal points 19 (see FIG. 4) of a laser beam 18 (see FIG. 4) to be emitted and arranging a plurality of processing marks 25 (modified layers) formed by irradiation with the laser beam 18 along a crystal orientation represented by formula (2) orthogonal to the crystal plane (3-3) which is relatively hardly cleaved.

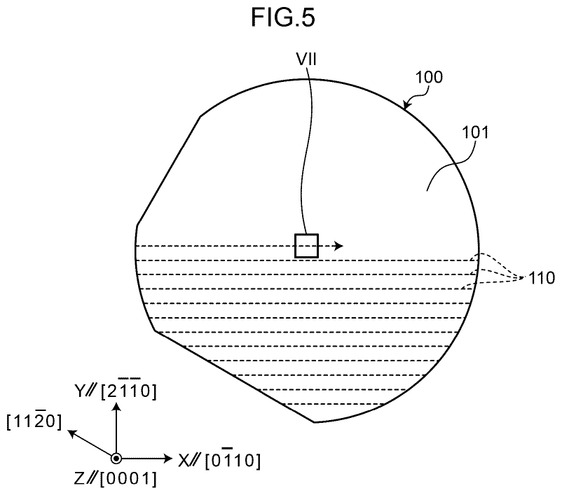

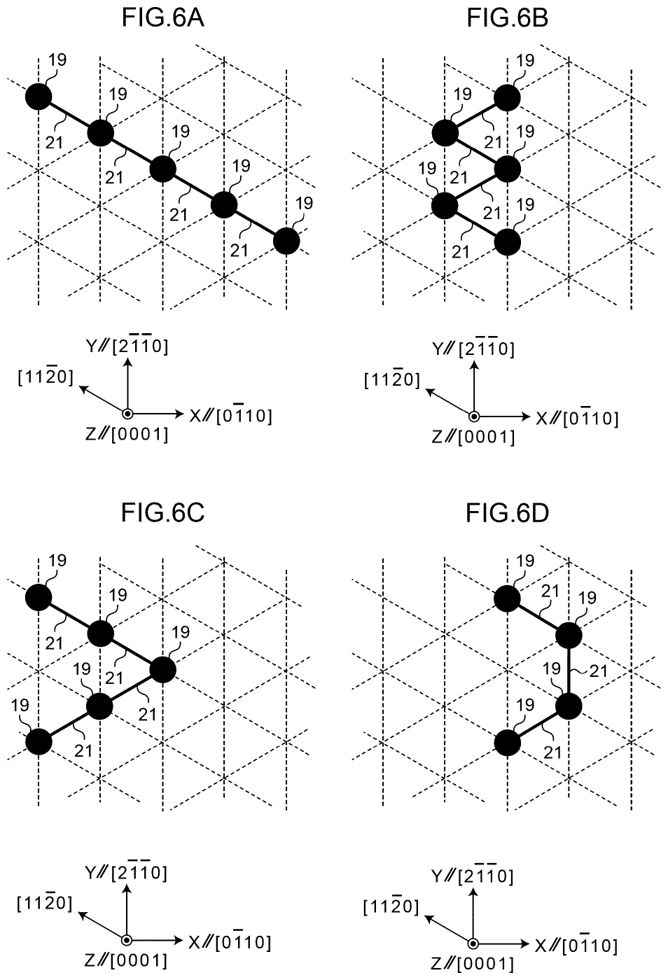

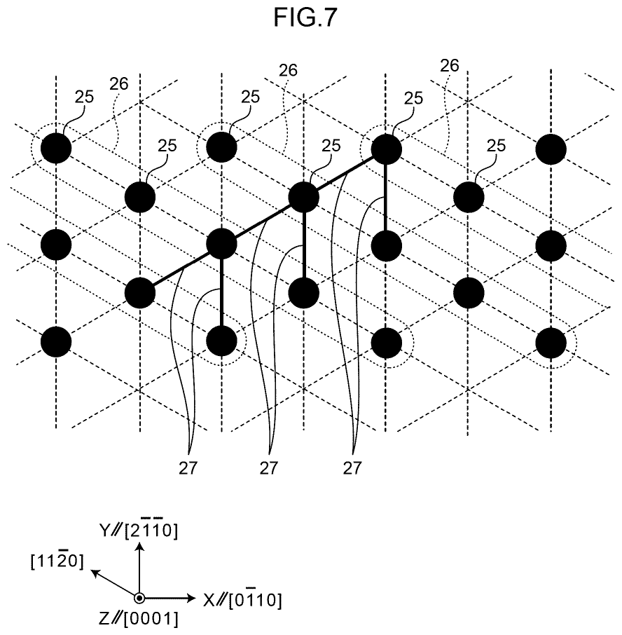

FIG. 4 is a cross-sectional view for explaining the holding step 1001 and the separating layer forming step 1002 in FIG. 3. FIG. 5 is a top view for explaining the separating layer forming step 1002 in FIG. 3. FIGS. 6A to 6D are top views for explaining branching of the laser beam 18 in the separating layer forming step 1002 in FIG. 3. FIG. 7 is a top view for explaining the processing marks 25 formed by the laser beam 18 in the separating layer forming step 1002 in FIG. 3. FIG. 7 is an enlarged view of VII in FIG. 5.

The holding step 1001 and the separating layer forming step 1002 are performed by a laser processing apparatus 10 illustrated in FIG. 4. As illustrated in FIG. 4, the laser processing apparatus 10 includes a holding table 11 that holds the GaN ingot 100 on a holding surface 12, an oscillator 13, an output adjustment unit 14, a branch unit 15, a mirror 16, a concentrator 17, a moving unit (not illustrated), and a control unit (not illustrated).

The holding table 11 is, for example, a chuck table that sucks and holds the GaN ingot 100 from the second surface 102 side on the holding surface 12 while the first surface 101 side of the GaN ingot 100 is exposed. The holding table 11 is disposed to be rotatable about an axis parallel to the Z-axis direction which is the vertical direction and perpendicular to the holding surface 12 by a rotary drive source (not illustrated).

The oscillator 13 oscillates the laser beam 18 having a wavelength transmissive to GaN (GaN ingot 100). The oscillator 13 includes, for example, Nd:YAG, Nd:YVO₄, or the like as a laser medium, and emits the pulsed (for example, several tens of MHz) laser beam 18 having a wavelength (for example, 1064 nm) transmissive to GaN (GaN ingot 100).

The output adjustment unit 14 adjusts an output of the laser beam 18 oscillated by the oscillator 13. The output adjustment unit 14 is, for example, an acousto-optic modulator (AOM), operates according to an input electric signal, deflects the laser beam 18 at predetermined time intervals according to the signal, and converts the laser beam 18 into a burst mode in which the laser pulse is thinned out at the predetermined time intervals. In the laser beam 18 adjusted by the output adjustment unit 14, in the present embodiment, a pulse repetition frequency is about several kHz to several tens kHz (for example, 50 kHz), and the number of bursts is about several to more than 10 and less than 20 (for example, 10).

The branch unit 15 branches the laser beam 18 whose output has been adjusted by the output adjustment unit 14 into a plurality of (about several to more than 10 and less than 20, five in the example illustrated in FIG. 4) beams at predetermined intervals in a predetermined direction in the XY plane. The branch unit 15 includes, for example, a liquid crystal on silicon-spatial light modulator (LCOS-SLM). Instead of the LCOS-SLM, a diffraction grating may be used.

The mirror 16 reflects the plurality of laser beams 18 branched by the branch unit 15 to change an optical axis direction. The concentrator 17 collects the plurality of laser beams 18 reflected by the mirror 16 to form the plurality of focal points 19, and irradiates the GaN ingot 100 with the laser beams. In the present embodiment, a spot diameter of the focal point 19 is set to about several μm (for example, about 5 μm).

The moving unit relatively moves the holding table 11 and the concentrator 17 along a processing feed direction and an indexing feed direction to relatively move the GaN ingot 100 held on the holding table 11 and the focal points 19 of the laser beams 18 formed by the concentrator 17 along the processing feed direction and the indexing feed direction. Here, in the present embodiment, the processing feed direction is set to the X-axis direction of the laser processing apparatus 10, and the indexing feed direction is set to the Y-axis direction of the laser processing apparatus 10.

The control unit of the laser processing apparatus 10 controls operation of each component of the laser processing apparatus 10 to cause the laser processing apparatus 10 to perform the holding step 1001 and the separating layer forming step 1002. The control unit of the laser processing apparatus 10 includes a computer system in the present embodiment. The computer system included in the control unit of the laser processing apparatus 10 includes an arithmetic processing device including a microprocessor such as a central processing unit (CPU), a storage device including a memory such as a read only memory (ROM) or a random access memory (RAM), and an input/output interface device. The arithmetic processing device of the control unit of the laser processing apparatus 10 performs arithmetic processing according to a computer program stored in the storage device of the control unit of the laser processing apparatus 10, and outputs a control signal for controlling the laser processing apparatus 10 to each component of the laser processing apparatus 10 via the input/output interface device of the control unit of the laser processing apparatus 10.

As illustrated in FIG. 4, the holding step 1001 is a step of holding the GaN ingot 100 by the holding table 11 of the laser processing apparatus 10. In the holding step 1001, specifically, the GaN ingot 100 is conveyed onto the holding table 11 by a conveying unit (not illustrated) or the like, the GaN ingot 100 is placed on the holding surface 12 with the first surface 101 side facing upward, the second surface 102 side of the GaN ingot 100 is sucked and held on the holding surface 12 of the holding table 11, then the holding table 11 is rotated about the Z-axis by a rotary drive source (not illustrated), the orientation flat 104 formed parallel to the crystal orientation (2-4) of the GaN ingot 100 is adjusted to a direction rotated by 30° from a direction along the processing feed direction (X-axis direction of the laser processing apparatus 10), and the orientation flat 105 formed parallel to the crystal orientation (2-3) of the GaN ingot 100 is adjusted to a direction rotated by 30° from a direction along the indexing feed direction (Y-axis direction of the laser processing apparatus 10). That is, in the holding step 1001, the crystal orientation (2-8) of the GaN ingot 100 held on the holding table 11 is set along the X-axis direction of the laser processing apparatus 10. Alternatively, the orientation flat 105 is adjusted to the X-axis direction of the laser processing apparatus 10, and the crystal orientation (2-9) is set along the X-axis direction.

The holding step 1001 is not limited to this in the present invention, and it is sufficient to set a specific crystal orientation included in the crystal orientation represented by the above formula (1) of the GaN ingot 100 held on the holding table 11 such that it is along the X-axis direction of the laser processing apparatus 10. Here, in the present embodiment, the specific crystal orientation included in the crystal orientation represented by formula (1) refers to any of the crystal orientations (2-3), (2-7), (2-8), (2-9), (2-10), and (2-11). In the present embodiment, adjustment (setting) along a predetermined orientation or direction refers to adjusting (setting) an angle formed with a predetermined orientation or direction to 10° or less.

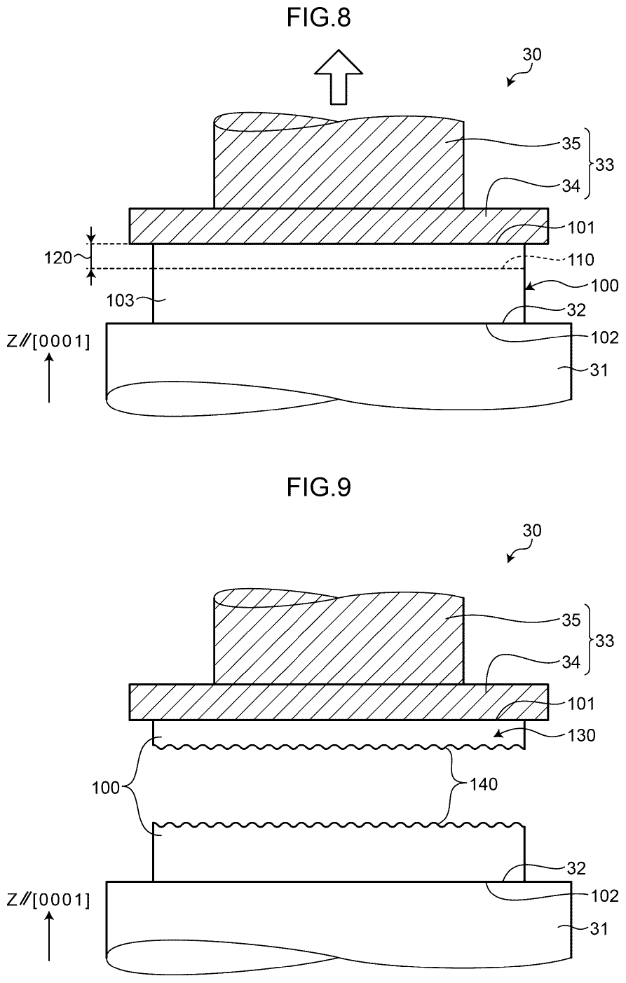

As illustrated in FIGS. 4 and 5, the separating layer forming step 1002 is a step of forming the separating layer 110 at a depth corresponding to a thickness 120 (see FIG. 8) of the GaN substrate 130 to be manufactured, by positioning the focal points 19 of the laser beam 18 having a wavelength transmissive to GaN (GaN ingot 100) inside the GaN ingot 100 from the first surface 101 and relatively moving the GaN ingot 100 and the focal points 19 along a direction of a crystal orientation represented by the above formula (1) of the GaN ingot 100.

In the present embodiment, the separating layer forming step 1002 includes a laser beam irradiation step and an indexing feed step. In the separating layer forming step 1002, by alternately performing the laser beam irradiation step and the indexing feed step after performing the holding step 1001, the separating layer 110 including a plurality of modified layers and cracks extending from the modified layers is formed along a direction parallel to the first surface 101 inside the GaN ingot 100.

The laser beam irradiation step is a step in which the control unit of the laser processing apparatus 10 forms modified layers and cracks extending from the modified layers along a direction parallel to the first surface 101 inside the GaN ingot 100 by irradiation with the laser beam 18 using the concentrator 17 while relatively moving (processing-feeding) the focal points 19 of the laser beam 18 and the GaN ingot 100 along a processing feed direction, that is, a direction of a specific crystal orientation (crystal orientation (2-8) in the present embodiment) parallel to the first surface 101 of the GaN ingot 100 and included in the crystal orientation represented by the above formula (1) using the moving unit. When the GaN ingot 100 is irradiated with the laser beam 18 in the laser beam irradiation step, modified layers are formed along a direction parallel to the first surface 101 in the vicinity of the focal points 19 of the laser beam 18 along a line parallel to the processing feed direction irradiated with the laser beam 18, and cracks extending from both sides of the modified layer along a direction parallel to the first surface 101 are formed. Note that the modified layers are, for example, regions in which density, refractive index, mechanical strength, and other physical properties are different from those of a surrounding region.

In the present embodiment, furthermore, in the laser beam irradiation step of the separating layer forming step 1002, the branch unit 15 of the laser processing apparatus 10 branches the laser beam 18 to form the plurality of focal points 19, and the plurality of focal points 19 is set such that straight line 21 connecting the branched focal points 19 is along a direction parallel to a direction of a specific crystal orientation included in the crystal orientation represented by the above formula (2). More specifically, in the laser beam irradiation step of the separating layer forming step 1002, as illustrated in FIGS. 6A to 6D, the plurality of focal points 19 formed by branching the laser beam 18 by the branch unit 15 is set such that the straight line 21 connecting the focal points 19 adjacent to each other is along a direction parallel to a direction of a specific crystal orientation included in the crystal orientation represented by formula (2).

In the laser beam irradiation step of the separating layer forming step 1002, an interval between the focal points 19 adjacent to each other is set to 5 μm or more and 20 μm or less for the plurality of focal points 19 formed by branching the laser beam 18 by the branch unit 15. In the present embodiment, a set value of the interval in the X-axis direction (direction parallel to the crystal orientation (2-8)) is, for example, 14.4 μm, and in this case, a set value of the interval in a direction parallel to the Y-axis direction is 12.5 μm. The focal points 19 adjacent to each other refer to a pair of focal points 19 in which an interval between the focal points 19 is within a range obtained by adding a predetermined error to the set value. In the present embodiment, the predetermined error is ±10% or less, preferably +5% or less of the set value.

In the laser beam irradiation step of the separating layer forming step 1002, by setting as described above, as illustrated in FIGS. 6A to 6D, all of the plurality of focal points 19 formed by branching the laser beam 18 by the branch unit 15 can be arranged so as to be located on intersections of cells which are formed by six orientations (including three crystal orientations represented by formula (2) and crystal orientations directed in opposite directions to the respective three crystal orientations) of specific crystal orientations included in the crystal orientation represented by formula (2) and in which the length of one side is a setting value of an interval between the focal points 19 adjacent to each other.

Specifically, in the branch pattern of the focal points 19 from the laser beam 18 illustrated in FIG. 6A, all four straight lines 21 connecting the focal points 19 adjacent to each other are along a direction parallel to the crystal orientation (2-4) in order from a lower side to an upper side of the paper surface of FIGS. 6A to 6D. In the branch pattern of the focal points 19 from the laser beam 18 illustrated in FIG. 6B, straight lines 21 connecting the focal points 19 adjacent to each other are along a direction parallel to the crystal orientation (2-4), along a direction parallel to the crystal orientation (2-5), along a direction parallel to the crystal orientation (2-4), and along a direction parallel to the crystal orientation (2-5) in order from a lower side to an upper side of the paper surface of FIGS. 6A to 6D. In the branch pattern of the focal points 19 from the laser beam 18 illustrated in FIG. 6C, straight lines 21 connecting the focal points 19 adjacent to each other are along a direction parallel to the crystal orientation (2-5), along a direction parallel to the crystal orientation (2-5), along a direction parallel to the crystal orientation (2-4), and along a direction parallel to the crystal orientation (2-4) in order from a lower side to an upper side of the paper surface of FIGS. 6A to 6D. In the branch pattern of the focal points 19 from the laser beam 18 illustrated in FIG. 6D, straight lines 21 connecting the focal points 19 adjacent to each other are along a direction parallel to the crystal orientation (2-5), along a direction parallel to the crystal orientation (2-6), and along a direction parallel to the crystal orientation (2-4) in order from a lower side to an upper side of the paper surface of FIGS. 6A to 6D.

In the present embodiment, furthermore, in the laser beam irradiation step of the separating layer forming step 1002, the control unit of the laser processing apparatus 10 relatively moves (processing-feeds) the GaN ingot 100 and the plurality of focal points 19 formed by branching the laser beam 18, thereby setting a moving speed (processing feed speed) between the GaN ingot 100 and the plurality of focal points 19 by the moving unit such that straight lines 27 connecting the formed adjacent processing marks 25 are formed along directions of specific crystal orientations included in the crystal orientation represented by the above formula (2) as illustrated in FIG. 7.

In the laser beam irradiation step of the separating layer forming step 1002, when the GaN ingot 100 is irradiated with the laser beam 18 forming a group of the plurality of focal points 19 illustrated in FIG. 6A, as illustrated in FIG. 7, a group of the plurality of processing marks 25 (processing mark group 26) having the same arrangement as the group of the plurality of focal points 19 is formed. Then, in the laser beam irradiation step of the separating layer forming step 1002, the control unit of the laser processing apparatus 10 sets the processing feed speed based on a time interval of irradiation with the laser beam 18 such that a product of the time interval of irradiation with the laser beam 18 and the processing feed speed is an integral multiple of (2×cos 30°×interval of focal points 19 adjacent to each other (length of straight line 21)) within a predetermined error range. Here, this integral multiple is preferably a minimum value such that the focal point 19 of the laser beam 18 to be emitted next does not overlap the position irradiated with the laser beam 18 immediately before, and for example, when the laser beam 18 having each of the patterns illustrated in FIGS. 6A, 6B, 6C, and 6D is emitted, it is preferable to set the processing feed speed with this integral multiple as 1 (equal). In the laser beam irradiation step of the separating layer forming step 1002, the processing feed speed is set to, for example, 1000 mm/s.

In the laser beam irradiation step of the separating layer forming step 1002, by setting the processing feed speed in this manner, as illustrated in FIG. 7, the straight lines 27 connecting the adjacent processing marks 25 between the formed adjacent processing mark groups 26 are formed along directions of specific crystal orientations included in the crystal orientation represented by the above formula (2). Then, as illustrated in FIG. 7, the processing marks 25 of the plurality of processing mark groups 26 formed by a plurality of times of irradiation with the laser beams 18 can be arranged so as to be located on intersections of cells which are formed by six types of specific crystal orientations included in the crystal orientation represented by formula (2) and in which the length of one side is a setting value of an interval between the focal points 19 adjacent to each other.

The indexing feed step is a step in which the control unit of the laser processing apparatus 10 relatively indexing-feeds, using the moving unit, the GaN ingot 100 and the focal points 19 of the laser beam 18 along an indexing feed direction, that is, a direction parallel to the first surface 101 of the GaN ingot 100 and orthogonal to a processing feed direction in which the GaN ingot 100 and the focal point 19 of the laser beam 18 are relatively moved when modified layers are formed in the laser beam irradiation step. In the present embodiment, in the indexing feed step of the separating layer forming step 1002, an indexing feed length (indexing feed amount) is set to about 100 μm (for example, 106 μm). The indexing feed amount may be set such that the processing mark group 26 formed in the laser beam irradiation step immediately before indexing feed and the processing mark group 26 formed in the laser beam irradiation step immediately after indexing feed partially overlap each other.

In the GaN ingot 100, modified layers are formed along a direction parallel to the first surface 101 in the vicinity of the focal points 19 of the laser beam 18 along a plurality of lines parallel to a processing feed direction by alternately performing the laser beam irradiation step and the indexing feed step, and cracks extending from the modified layers formed along adjacent lines are connected to each other. As a result, by application of a predetermined external force to the GaN ingot 100, the GaN substrate 130 including the first surface 101 and having the thickness 120, which corresponds to a depth from the first surface 101 when the focal points 19 of the laser beam 18 are positioned inside the GaN ingot 100, can be separated with the separating layer 110 including these modified layers and cracks as starting points.

FIGS. 8 and 9 are both cross-sectional views for explaining the separating step 1003 in FIG. 3. As illustrated in FIGS. 8 and 9, the separating step 1003 is a step of separating the GaN substrate 130 from the GaN ingot 100 with the separating layer 110 as a starting point. The separating step 1003 is performed by a separating device 30 illustrated in FIGS. 8 and 9. As illustrated in FIGS. 8 and 9, the separating device 30 includes a holding table 31 that holds the GaN ingot 100 on a holding surface 32, a separating unit 33, and a control unit (not illustrated).

The holding table 31 is similar to the holding table 11 of the laser processing apparatus 10 described above. The separating unit 33 includes a suction holder 34 and a moving unit 35. The suction holder 34 is formed in a disk shape, and sucks and holds the first surface 101 of the GaN ingot 100 on a lower surface thereof. The moving unit 35 relatively moves the holding table 31 and the suction holder 34, for example, along the Z-axis direction. The moving unit 35 can apply a force to pull the GaN ingot 100 along the Z-axis direction by applying power to the suction holder 34 that sucks and holds the first surface 101 of the GaN ingot 100 held on the holding table 31 in a direction relatively separating the suction holder 34 from the holding table 31 along the Z-axis direction. The control unit of the separating device 30 includes a computer system similar to the control unit of the laser processing apparatus 10.

In the separating step 1003, as illustrated in FIGS. 8 and 9, the GaN ingot 100 is sucked and held from the second surface 102 side on the holding surface 32 of the holding table 31 while the first surface 101 side is exposed, the suction holder 34 of the separating unit 33 sucks and holds the first surface 101 of the GaN ingot 100, and then the moving unit 35 of the separating unit 33 applies a pulling force along the Z-axis direction to the GaN ingot 100 held on the holding table 31, thereby separating the GaN substrate 130 from the GaN ingot 100 at a separating surface 140 with the separating layer 110 as a starting point.

In the method for manufacturing a gallium nitride substrate according to the embodiment, an external force applying step such as insertion of a wedge or application of an ultrasonic wave may be performed after performing the separating layer forming step 1002 and before performing the separating step 1003 or simultaneously with performing the separating step 1003.

In the external force applying step, for example, a wedge is driven into the peripheral surface 103 of the GaN ingot 100 at a height position of the separating layer 110, whereby cracks of the separating layer 110 can be further extended along a direction parallel to the first surface 101. The wedge may be driven at one location, or may be driven at a plurality of locations along a circumferential direction of the GaN ingot 100.

In the external force applying step, the cracks of the separating layer 110 can be further extended along a direction parallel to the first surface 101 also by applying an ultrasonic wave (elastic vibration wave in a frequency band exceeding 20 kHz) to the GaN ingot 100 instead of driving a wedge. In this case, in the external force applying step, an ultrasonic wave is applied to the first surface 101 side via a liquid such as pure water before a lower surface of the suction holder 34 sucks and holds the first surface 101 of the GaN ingot 100. Specifically, in the external force applying step, a liquid to which an ultrasonic wave is applied may be injected toward the first surface 101 of the GaN ingot 100, or an ultrasonic wave may be applied from an ultrasonic horn to the first surface 101 side of the GaN ingot 100 via a liquid. Furthermore, in the external force applying step, on the first surface 101 side of the GaN ingot 100, first, an ultrasonic wave is applied to a local region having a diameter of about 5 mm to 50 mm, and then, a region to be applied with the ultrasonic wave applied is gradually widened, whereby the cracks of the separating layer 110 can be more preferably further extended along a direction parallel to the first surface 101.

By performing the external force applying step, cracks are connected between adjacent modified layers, and mechanical strength of the separating layer 110 is further weakened as compared with a region other than the separating layer 110 of the GaN ingot 100. Therefore, the GaN substrate 130 can be separated from the GaN ingot 100 with a smaller force than that when the external force applying step is not performed.

In the method for manufacturing a gallium nitride substrate according to the embodiment having the above configuration, in the separating layer forming step 1002, the branch unit 15 of the laser processing apparatus 10 branches the laser beam 18 to form the plurality of focal points 19, and the plurality of focal points 19 is set such that the straight line 21 connecting the branched focal points 19 is along a direction parallel to a direction of a specific crystal orientation included in the crystal orientation represented by the above formula (2). Therefore, in the method for manufacturing a gallium nitride substrate according to the embodiment, the group of the plurality of processing marks 25 (modified layers) formed by irradiation with the laser beam 18 can be arranged such that the straight line 21 connecting the processing marks 25 (modified layers) adjacent to each other is along a direction parallel to a direction of a specific crystal orientation included in a crystal orientation represented by the above formula (2) similarly to the focal points 19. Therefore, it is possible to reduce a possibility of generating a crack (cleavage) along the crystal plane (3-2) which is a cause for increasing unevenness of the separating surface 140. For this reason, the method for manufacturing a gallium nitride substrate according to the embodiment can reduce unevenness of the separating surface 140 by preferably extending cracks of the separating layer 110 along a direction parallel to the first surface 101, and thereby has an effect that the GaN substrate 130 can be efficiently cut out from the GaN ingot 100 and manufactured.

In the method for manufacturing a gallium nitride substrate according to the embodiment, the control unit of the laser processing apparatus 10 relatively moves (processing-feeds) the GaN ingot 100 and the plurality of focal points 19 formed by branching the laser beam 18, thereby setting a moving speed (processing feed speed) between the GaN ingot 100 and the plurality of focal points 19 by the moving unit such that the straight line 27 connecting the formed adjacent processing marks 25 is formed along a direction of a specific crystal orientation included in the crystal orientation represented by the above formula (2) as illustrated in FIG. 7. Therefore, in the method for manufacturing a gallium nitride substrate according to the embodiment, the processing marks 25 of the plurality of processing mark groups 26 formed by a plurality of times of irradiation with the laser beams 18 can be arranged such that the straight line 21 connecting the adjacent processing marks 25 (modified layers) between the processing mark groups 26 adjacent to each other is along a direction parallel to a direction of a specific crystal orientation included in the crystal orientation represented by the above formula (2) similarly to the focal points 19. Therefore, it is possible to further reduce a possibility of generating a crack (cleavage) along the crystal plane (3-2) which is a cause for increasing unevenness of the separating surface 140. For this reason, the method for manufacturing a gallium nitride substrate according to the embodiment can further reduce unevenness of the separating surface 140 by more preferably extending cracks of the separating layer 110 along a direction parallel to the first surface 101, and thereby has an effect that the GaN substrate 130 can be more efficiently cut out from the GaN ingot 100 and manufactured.

In the method for manufacturing a gallium nitride substrate according to the embodiment, the processing feed direction is set along a direction parallel to a direction of a specific crystal orientation included in the crystal orientation represented by the above formula (1). Therefore, the method has an effect that it is possible to reduce a laser output necessary for forming cracks of the separating layer 110 and to contribute to reduction of a damaged layer and improvement of processing capability. That is, the method has an effect that, by positioning the focal point 19 inside the gallium nitride ingot 100 in a state in which the laser beam 18 is branched such that the processing marks 25 (modified layers) are along a direction parallel to a direction of a specific crystal orientation included in the crystal orientation represented by the above formula (2), and relatively moving the focal points 19 and the gallium nitride ingot 100 in a direction parallel to a direction of a specific crystal orientation included in the crystal orientation represented by the above formula (1), it is possible to reduce crack formation failure and excessive crack formation, and to efficiently and uniformly form cracks. As a result, the amount of a material discarded by slicing with a wire saw can be largely reduced. Therefore, the gallium nitride substrate 130 can be manufactured without waste from the gallium nitride ingot 100, and productivity can be improved.

According to the present invention, a gallium nitride substrate can be efficiently cut out from a gallium nitride ingot and manufactured.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for manufacturing a gallium nitride substrate from a gallium nitride ingot having a first surface and a second surface on a side opposite to the first surface, the method comprising:
holding the gallium nitride ingot;
forming a separating layer at a depth corresponding to a thickness of the gallium nitride substrate to be manufactured, by positioning a focal point of a laser beam having a wavelength transmissive to gallium nitride inside the gallium nitride ingot from the first surface and relatively moving the gallium nitride ingot and the focal point along a direction of a crystal orientation represented by the following formula (1) of the gallium nitride ingot; and
separating the gallium nitride substrate from the gallium nitride ingot with the separating layer as a starting point, wherein
the separating includes forming a plurality of focal points by branching the laser beam and setting the focal points such that a straight line connecting the branched focal points is along a direction parallel to a direction of a crystal orientation represented by the following formula (2). [symbol]
1 0 1̅ 0 [symbol] formula (1) [symbol]
1 1 2̅ 0 [symbol] formula (2)

2. The method for manufacturing a gallium nitride substrate according to claim 1, wherein
the separating layer includes setting moving speeds of the gallium nitride ingot and the focal points are set such that a straight line connecting adjacent processing marks formed by relatively moving the gallium nitride ingot and the focal points is formed along a direction of a crystal orientation represented by the above formula (2).
